(19) United States
(12) Patent Application Publication
(10) Pub. No.: US 2015/0262911 A1
(43) Pub. Date: Sep. 17, 2015

(54) TSV WITH END CAP, METHOD AND 3D INTEGRATED CIRCUIT

(71) Applicant: International Business Machines Corporation, Armonk, NY (US)

(72) Inventors: Fen Chen, Williston, VT (US); Jeffrey P. Gambino, Westford, VT (US); Charles W. Griffin, Jericho, VT (US); Zhong-Xiang He, Essex Junction, VT (US); Anthony K. Stamper, Williston, VT (US)

(73) Assignee: International Business Machines Corporation, Armonk, NY (US)

(21) Appl. No.: 14/211,479

(22) Filed: Mar. 14, 2014

(51) Int. Cl. H01L 23/48; H01L 21/304; H01L 21/3205; H01L 21/768; H01L 21/306

(52) U.S. Cl. CPC H01L 23/481; H01L 21/76898; H01L 21/76844; H01L 21/30604; H01L 21/32053; H01L 21/304

(57) ABSTRACT

A through silicon via (TSV), method and 3D integrated circuit are disclosed. The TSV extends through a substrate to a back side of the substrate and includes a body including a first metal for coupling to an interconnect on a front side of the substrate. A dielectric collar insulates the body from the substrate. The TSV also includes an end cap coupled to the body on the back side of the substrate, the end cap including a second metal that is different than the first metal. The end cap acts as a grinding stop indicator during back side grinding for 3D integration processing, preventing damage to the dielectric collar and first metal (e.g., copper) contamination of the substrate.

### BACKGROUND

1. Technical Field

The disclosure relates generally to integrated circuit (IC) chip processing, and more particularly, to a through silicon via having an end cap and related processing.

2. Background Art

A through silicon via (TSV) is a vertically extending interconnect that passes through a silicon wafer or die. TSVs are commonly used in three-dimensional (3D) integration of integrated circuit (IC) chips. For example, TSVs may be used on a back side of a first IC chip for interconnection to wiring, e.g., solder bumps, or interconnection to another IC chip. During the 3D integration process, a first fully processed wafer including circuitry, e.g., field effect transistors (FETs), back-end-of-line metal interconnects, etc., is built including a TSV through a substrate (e.g., silicon) thereof. The TSV typically includes an insulative collar (e.g., of silicon dioxide (oxide)) about a metal interior (e.g., of copper) to prevent diffusion of the metal of the TSV into the substrate that surrounds it, which could cause a short. A conventional refractory metal liner may also be employed. Once the fully processed wafer is formed, it is coupled to a handle wafer at a front end thereof, and the substrate containing the TSV is recessed to expose the TSV at a back end of the substrate. The recessing on the back side may include, for example, grinding off the substrate and performing a dry etch to expose the TSV and oxide collar beyond a surface of the substrate. An interlayer dielectric (ILD) layer (e.g., of silicon dioxide) may then be formed over the exposed TSV and planarized to expose the end of the TSV. Metal interconnects to the TSV can then be made on or in the ILD layer. In this fashion, a 3D integration to wiring on the back side of the first IC chip can be made using the TSV, or another IC chip can be electrically coupled to the first IC chip.

One challenge for 3D integration yield and reliability is controlling TSV-to-substrate leakage and breakdown due to oxide collar damage caused during the processing. More specifically, during processing the oxide collar can be damaged, causing metal diffusion from the TSV to the substrate, which presents a serious concern for 3D integration chip yield and reliability. Currently, precise TSV depth control is the only solution to minimize this problem. Unfortunately, achieving a uniform TSV depth across an IC chip and across a wafer for thousands of TSVs per chip is very challenging. Consequently, the collar of a TSV can be damaged by a number of processes. For example, the oxide collar can be damaged during the substrate recessing to expose the TSV. In particular, the grinding to remove the substrate may impact the oxide collar causing metal contamination of the substrate. In another example, the backside metal deposition and related processing (e.g., grinding or chemical mechanical polishing) can cause oxide collar damage. In particular, the CMP of the ILD layer is supposed to expose an end of all the TSVs. But, where TSV depths differ, it is very difficult to ensure exposure of the ends of all of the TSVs with no damage to the oxide collars across all of the TSVs.

### BRIEF SUMMARY

A first aspect of the disclosure provides a through silicon via (TSV) extending through a substrate to a back side of the substrate, the TSV comprising: a body including a first metal for coupling to an interconnect on a front side of the substrate; a dielectric collar insulating the body from the substrate; and an end cap coupled to the body on the back side of the substrate, the end cap including a second metal that is different than the first metal.

A second aspect of the disclosure provides a method comprising: forming a device layer on a substrate; forming a through silicon via (TSV) opening in the substrate, the TSV opening including a dielectric collar and a bottom exposing the substrate; forming an end cap in a bottom of the TSV opening, the end cap including a first metal; forming a TSV by forming a body including a second metal that is different than the first metal in the TSV opening.

A third aspect of the disclosure provides a three dimensional integrated circuit comprising: an integrated circuit chip including a through silicon via having: a body including a first metal for coupling to an interconnect on a front side of the substrate, a dielectric collar insulating the body from the substrate, and an end cap coupled to the body on the back side of the substrate, the end cap including a second metal that is different than the first metal; and a backside metallization coupled to the end cap on a back side of the substrate.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIGS. 1-12 show cross-sectional views of various steps of a method according to embodiments of the invention with FIGS. 3, 5, 7 and 12 showing embodiments of a through silicon via according to embodiments of the invention.

FIGS. 13-16 show cross-sectional views of various additional steps of a method according to embodiments of the invention with FIG. 16 showing one embodiment of a three dimensional integrated circuit according to embodiments of the invention.

It is noted that the drawings of the disclosure are not to scale. The drawings are intended to depict only typical aspects of the disclosure, and therefore should not be considered as limiting the scope of the disclosure. In the drawings, like numbering represents like elements among the drawings.

### DETAILED DESCRIPTION

As indicated above, the disclosure provides a through silicon via (TSV), method and 3D integrated circuit. The TSV extends through a substrate to a back side of the substrate and includes a body including a first metal for coupling to an interconnect on a front side of the substrate. A dielectric collar insulates the body from the substrate. The TSV also includes an end cap coupled to the body on the back side of the substrate, the end cap includes a second metal that is different than the first metal. In embodiments, the end cap may include a non-copper metal or a non-copper metal alloy. As will be described, the end cap acts as a grinding stop indicator during back side grinding for 3D integration processing, preventing damage to the dielectric collar and metal (e.g., copper) contamination of the substrate.

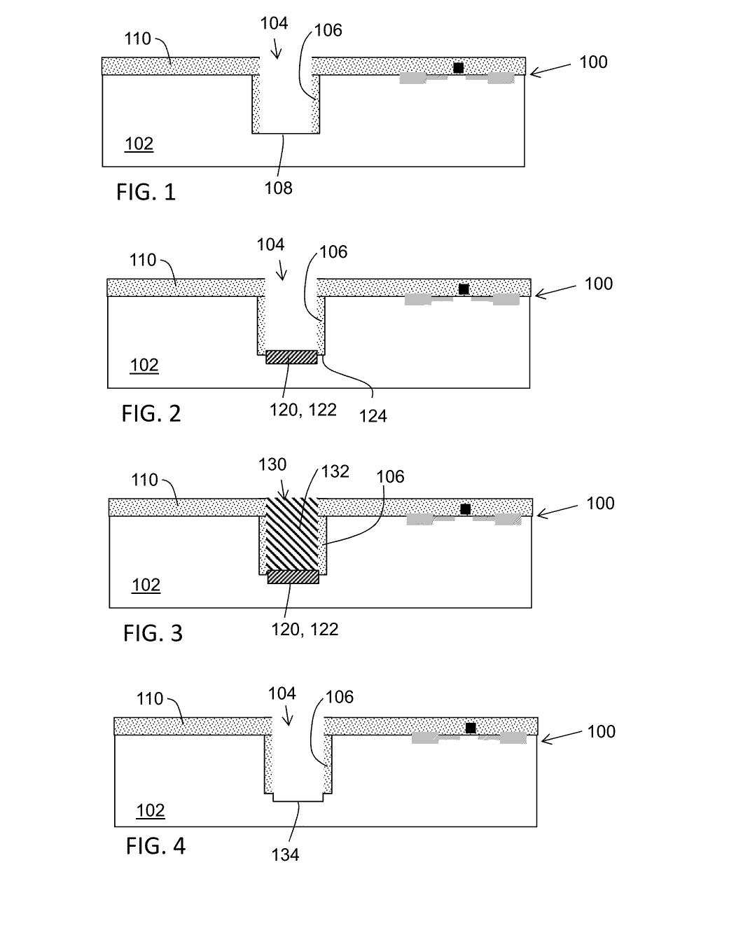

Referring to the drawings, a method of forming a through silicon via (TSV) will be described. FIG. 1 shows an initial step of a method according to embodiments of the invention. In this stage, a device layer 100 has been formed on a substrate 102, e.g., with an inter layer dielectric (ILD) layer thereover. Device layer 100 may include any now known or later developed integrated circuit devices, e.g., transistors, resistors, isolations, etc. Substrate 102 may include but is not limited to silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Furthermore, a portion or entire substrate 102 may be strained. For example, an SOI layer and/or epi layer thereof (neither shown for clarity) may be strained.

Also shown in FIG. 1 is forming a through silicon via (TSV) opening 104 in substrate 102. TSV opening 104 may be formed using any now known or later developed technique, e.g., depositing, patterning and etching a photoresist, and etching the opening. As shown, TSV opening 104 includes a dielectric collar 106 and a bottom 108 exposing substrate 102. Dielectric collar 106 may be formed by etching opening 104 into substrate 102, as described, and forming a dielectric layer 110 over the opening. (Dielectric layer 110 may overlay an ILD layer over device layer 100, not shown for clarity). A spacer etch such as a reactive ion etch can then be performed to expose substrate 102 in bottom 108 of opening 104 and form dielectric collar 106. In one embodiment, dielectric collar 106 includes silicon oxide (SiO₂) (oxide), but it may include other materials such as but not limited to: silicon nitride (Si₃N₄), fluorinated SiO₂ (FSG), hydrogenated silicon oxycarbide (SiCOH), porous SiCOH, boro-phospho-silicate glass (BPSG), silsesquioxanes, carbon (C) doped oxides (i.e., organosilicates) that include atoms of silicon (Si), carbon (C), oxygen (O), and/or hydrogen (H), thermosetting polyarylene ethers, SiLK (a polyarylene ether available from Dow Chemical Corporation), a spin-on silicon-carbon containing polymer material available form JSR Corporation, other low dielectric constant (<3.9) material, or layers thereof.

Dielectric layer 110 may be deposited over using any now known or later developed method. Dielectric layer 110 may include any interlayer dielectric layer such as those listed above for dielectric collar 106. Unless otherwise specified, “depositing” may include any now known or later developed techniques appropriate for the material to be deposited including but not limited to: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

Referring to FIGS. 2-12, various embodiments for forming an end cap including a first metal in bottom 108 of TSV opening 104 are illustrated. As will be described, after end cap 120 formation, as shown for example in FIG. 3, a TSV 130 is formed by forming a body 132 in TSV opening 104 (FIG. 2). As will be described, body 132 includes a second metal that is different than the first metal. For example, although other options will be described, end cap 120 metal may include a silicide such as nickel silicide or a refractory metal such as tungsten, and body 132 metal may include copper. (Note: the terms “first metal” is used in the detailed description to refer to the end cap metal and “second metal” is used to refer to the TSV body metal. In the claims, however, the terms may refer to body 132 or the various end caps, depending on the context of the claim.)

Referring to FIG. 2, in one embodiment, end cap 120 forming may include forming the first metal as a silicide 122 on bottom 108 (FIG. 1) of TSV opening 104. Silicide 122 may be formed using any now known or later developed technique, e.g., performing an in-situ pre-clean, depositing a metal such as titanium, nickel, cobalt, etc., annealing to have the metal react with silicon, and removing unreacted metal. In this case, any self-aligned silicide processing will work. As understood, the metal only reacts to form silicide 122 where silicon of substrate 102 is exposed. The metal removal process may include, for example, a wet etch to remove the first metal but not the silicide. As shown in FIG. 2, end cap 120 extends into substrate 102 beyond an end 124 of dielectric collar 106.

Referring to FIG. 3, TSV 130 may be formed by forming body 132 in TSV opening 104 (FIG. 2) including a second metal that is different than silicide 122. The TSV body metal may be deposited by any technique listed herein, and may be followed by any now known or later developed processing, such as CMP, i.e., chemical-mechanical polishing for surface planarization and definition of metal interconnect patterns. Although copper has been stated as one metal for TSV body 132, the TSV body metal may include copper, tungsten, aluminum, tin, silver or gold. Although not shown for clarity, as understood in the art, any now known or later developed liner may be employed to prevent diffusion of copper from body 132. As known in the art, the liner typically includes a refractory metal alloy such as: tantalum nitride (TaN)/tantalum; however, other refractory metals such as tantalum (Ta), titanium (Ti), tungsten (W), iridium (Ir), rhodium (Rh) and platinum (Pt), etc., or mixtures thereof, may also be employed.

As will be described in greater detail, TSV 130 with end cap 120 provides a mechanism for preventing damage to collar 106 and/or the liner of body 132 during 3D integration processing, and especially during back side grinding of substrate 102. In this fashion, end cap 120 acts as a grinding stop indicator that when exposed allows for high conductivity connection to TSV 130 yet prevents damage to collar 106 and/or the liner of body 132.

Referring to FIG. 4, a step that may be employed for a number of alternative embodiments for forming an end cap includes etching a recess 134 into substrate 102 at bottom 108 (FIG. 1) of opening 104 as part of TSV opening 104 forming, i.e., after the processing of FIG. 1. Recess 134 may be formed using any now known or later developed etching process selective to substrate 102, e.g., a silicon reactive ion etch (RIE) where substrate 102 includes silicon.

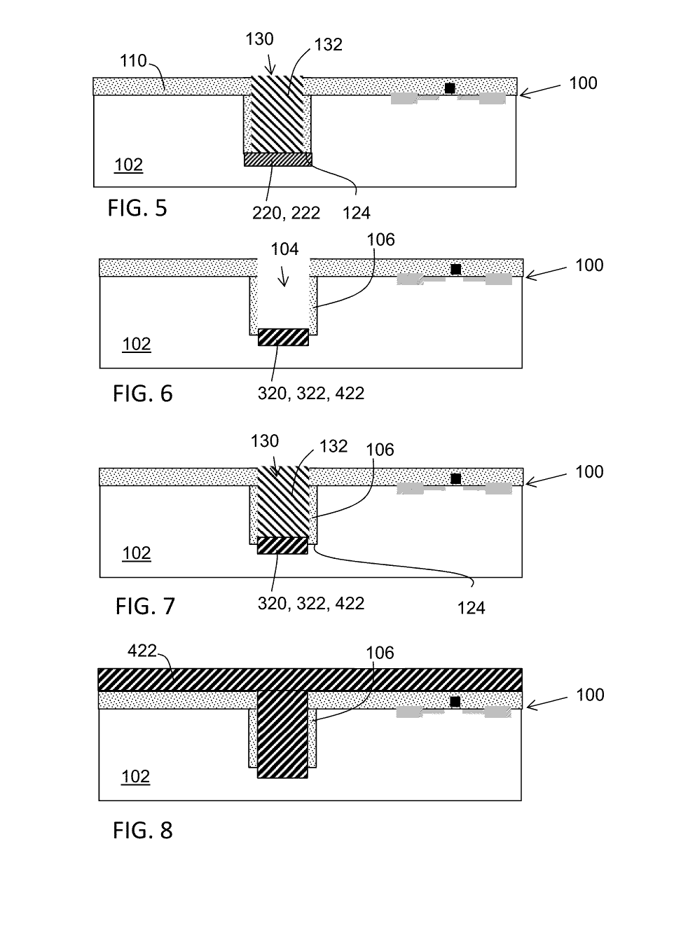

Referring to FIG. 5, in one embodiment, an end cap 220 forming may include forming the first metal as a silicide 222 on bottom 108 (FIG. 1) of TSV opening 104 with recess 134 (FIG. 4) therein. Silicide 222 may be formed as described herein. TSV 130 may be formed, as described herein, by forming body 132 in TSV opening 104 (FIG. 2) including a second metal, e.g., copper, that is different than silicide 222. As shown in FIG. 5, end cap 320 extends into substrate 102 beyond end 124 of dielectric collar 106. In addition, due to recess 134 (FIG. 4), end cap 220 may also extend (laterally) beyond end 124 of dielectric collar 106 (and liner of body 132), which provides additional protection against damage to the collar during 3D integration processing, e.g., back side grinding.

Referring to FIG. 6, in another embodiment, an end cap 320 forming may include selectively depositing first metal 322 in bottom 108 (FIG. 1) of TSV opening 104 (FIG. 1), which includes recess 134 (FIG. 4). In this case, deposition may include, for example, chemical vapor deposition adjusted to deposit tungsten selectively on substrate 102 (e.g., silicon) and not dielectric collar 106. TSV 130 may be formed, as described herein, by forming body 132 in TSV opening 104 (FIG. 2) including a second metal (e.g., copper) that is different than the tungsten. As shown in FIG. 7, end cap 320 extends into substrate 102 beyond end 124 of dielectric collar 106. Here, however, end cap 320 does not extend (laterally) beyond end 124 of dielectric collar 106 (and liner of body 132). TSV 130 may be formed, as described herein, by forming body 132 in TSV opening 104 (FIG. 2) including, e.g., copper. As shown in FIG. 7, end cap 320 extends beyond end 124 of dielectric collar 106. Here, however, end cap 320 does not extend (laterally) over end 124 of dielectric collar 106 (and liner of body 132).

End cap 320, as shown in FIG. 7, may also be formed using a blanket deposition of a first metal. More particularly, as shown in FIG. 8, in another embodiment, end cap 320 forming may include blanket depositing first metal 422 into TSV opening 104 (FIG. 1) and etching the first metal 422 to form end 320 cap, leaving dielectric collar 106. The resulting structure is substantially identical to that shown in FIG. 6. In this embodiment, first metal 422 may include a refractory metal such as tungsten. As again shown in FIG. 7, TSV 130 may be formed, as described herein, by forming body 132 in TSV opening 104 including, e.g., copper. As shown in FIG. 7, end cap 320 extends beyond end 124 of dielectric collar 106 into substrate 102. Here, however, end cap 320 does not extend (laterally) beyond end 124 of dielectric collar 106 (and liner of body 132).

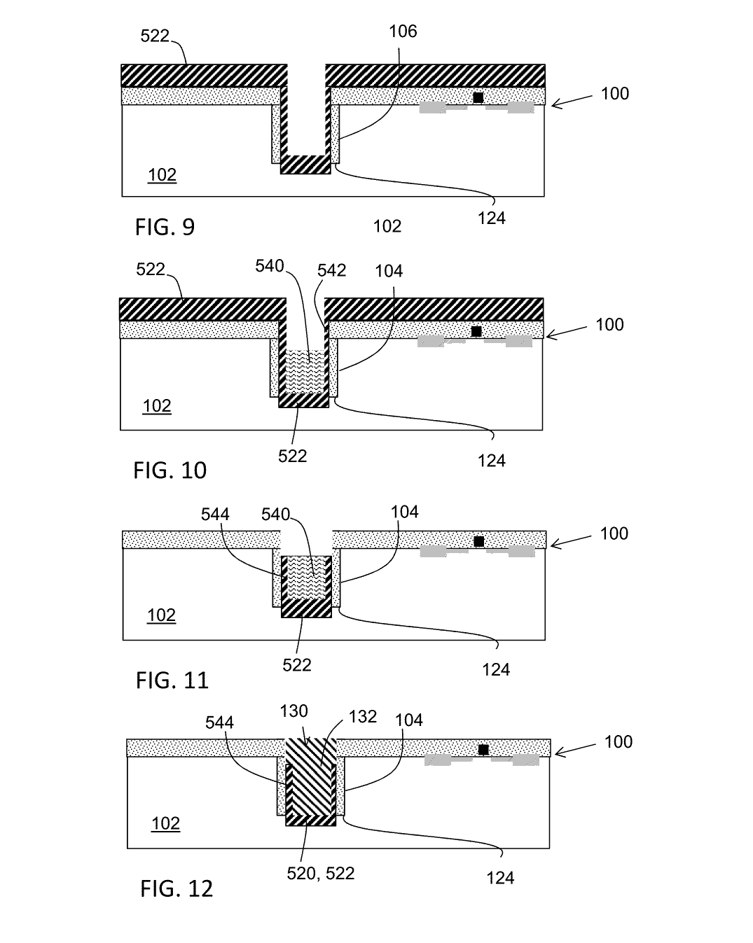

FIGS. 9-12 show another embodiment of forming an end cap 520 (FIG. 12) from TSV opening 104 embodiment shown in FIG. 4, i.e., with recess 134. In this embodiment, first metal 522, e.g., tungsten, is deposited on a sidewall of opening 104 (FIG. 4) and recessed 134 bottom (FIG. 4) of the opening. First metal 522 (e.g., tungsten) may be deposited using any now known or later developed columnated deposition technique, e.g., sputter deposition and variants such as ionized physical vapor deposition or CVD. Next, as shown in FIG. 10, a resist plug 540 is formed over first metal 522 in TSV opening 104. Resist plug 540 may be formed using any appropriate resist and application technique, e.g., by applying a photoresist over first metal 522 and etching to remove the photoresist except within opening 104. FIG. 11 shows, inter alia, removing an upper portion 542 (FIG. 10) of first metal 522 from TSV opening 104 by etching, forming a first metal collar 544 about resist plug 540. The etching may include, for example, a wet etch selective to first metal 522, e.g., tungsten. FIG. 12 shows etching to remove resist plug 540 (e.g., RIE), and forming TSV 130 by forming body 132 by depositing the second metal, e.g., copper, into TSV opening 104 (FIG. 4) within first metal (e.g., tungsten) collar 544 and over end cap 520.

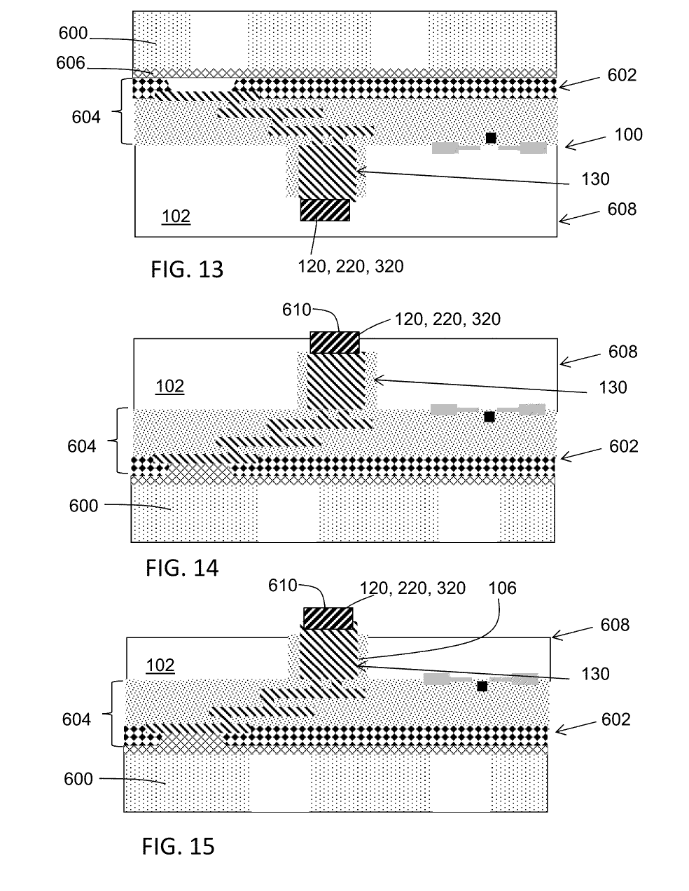

FIGS. 13-16 show additional steps of a method according to embodiments of the invention illustrating one application of TSV 130. In the example, the methods may further include bonding a handle wafer 600 to a front side 602 of substrate 102 over device layer 100. As illustrated, device layer 100 includes a number of back-end-of-line (BEOL) layers 604 thereover. As understood, BEOL layers 604 refer to layers formed on the semiconductor wafer in the course of device manufacturing following first metallization, i.e., first interconnect layer to device layer 100. BEOL layers 604 act to scale the resulting IC chip wiring and make wiring connections to device layer 100. Handle wafer 600 may include any now known or later developed material, e.g., glass, and may be coupled to BEOL layers 604 using any conventional adhesive layer 606.

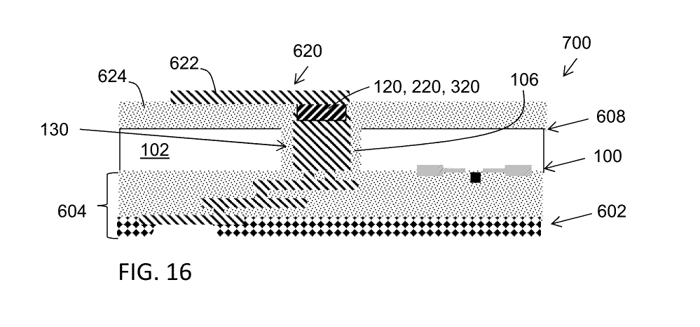

FIG. 14 shows the structure of FIG. 13 in a flipped arrangement, and also grinding of a back side 608 of substrate 102 until a surface 610 of end cap 120, 220, 320 is exposed. Grinding may be carried out using any conventional technique. Exposure of surface 610 provides an indication of where grinding should stop, exposes a highly conductive end cap 120, 220, 320 coupled to TSV 130, but without damaging dielectric collar 106 and/or any liner used with TSV 130. As shown in FIG. 15, recessing substrate 102 beyond surface 610 of end cap 120, 220 (prior to forming backside metallization) may also be performed at this stage. Recessing may include any appropriate etching, e.g., a dry etch, to recess substrate 102 and dielectric collar 106. Finally, as shown in FIG. 16, a backside metallization 620 may be formed to end cap 120, 220, 320 and thus to TSV 130. Backside metallization 620, as illustrated, includes a metal wire 622 formed above a planarized interlayer dielectric layer 624 about TSV 130 and end cap 120, 220, 320. However, as understood in the art, backside metallization 620 may include any controlled collapse chip connect (C4), planar metal, patterned metal, etc.

Although FIGS. 13-16 have been described relative to embodiments of end cap 120, 220, 320, it is emphasized that the teachings of FIGS. 13-16 are equally applicable to other embodiments of end cap 520 (FIG. 12).

FIG. 16 also illustrates a TSV 130 according to embodiments extending through substrate 102 to back side 608 of the substrate. As described, TSV 130 includes a body 132 including a first metal, such as copper, for coupling to an interconnect (BEOL layers 604) on front side 602 of substrate 102. A dielectric collar 106 insulates body 132 from substrate 102, and end cap 120, 220, 320, 520 (latter in FIG. 12) couples to body 132 on back side 608 of substrate 102 and includes a second metal (e.g., silicide such as nickel silicide or a refractory metal such as tungsten) that is different than the first metal (e.g., copper). As described, end cap 120, 220, 320, 520 indicates a grinding stop point during grinding to remove a back side of the substrate for three dimensional integration processing. In embodiments, end cap 120, 220, 320, 520 may extend into substrate 102 past an end 124 of dielectric collar 106, to protect end 124 from grinding. The metal of the body of TSV 132 may include copper and the metal of end cap 120, 220, 320, 520 may include one of: a silicide such as nickel silicide and a refractory metal such as tungsten. Although various embodiments of end cap materials have been described herein, it is emphasized that where TSV 130 includes copper, the end cap can include any conductive metal that is a non-copper metal and a non-copper metal alloy. FIG. 16 also illustrates a three dimensional integrated circuit 700 that includes an integrated circuit chip (device layer 100, BEOL layers 604, etc.) including TSV 130.

The method as described above is used in the fabrication of integrated circuit chips, and in particular, three dimensional integrated circuits. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from cell phones, toys and other low-end applications to advanced computer products having a display, a keyboard or other input device, and a central processor.

The foregoing drawings show some of the processing associated according to several embodiments of this disclosure. In this regard, each drawing or block within a flow diagram of the drawings represents a process associated with embodiments of the method described. It should also be noted that in some alternative implementations, the acts noted in the drawings or blocks may occur out of the order noted in the figure or, for example, may in fact be executed substantially concurrently or in the reverse order, depending upon the act involved. Also, one of ordinary skill in the art will recognize that additional blocks that describe the processing may be added.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A through silicon via (TSV) extending through a substrate to a back side of the substrate, the TSV comprising:
a body including a first metal for coupling to an interconnect on a front side of the substrate;
a dielectric collar insulating the body from the substrate; and
an end cap coupled to the body on the back side of the substrate, the end cap including a second metal that is different than the first metal.

2. The TSV of claim 1, wherein the end cap indicates a grinding stop point during grinding to remove a back side of the substrate for three dimensional integration processing.

3. The TSV of claim 1, wherein the end cap extends past an end of the dielectric collar.

4. The TSV of claim 1, wherein the first metal includes copper and the second metal includes one of: a silicide and a refractory metal.

5. The TSV of claim 4, wherein the silicide includes nickel, and the refractory metal includes tungsten.

6. The TSV of claim 1, wherein the first metal includes copper and the second metal includes one of a non-copper metal and a non-copper metal alloy.

7. The TSV of claim 1, wherein the end cap couples to a backside metallization.

8. A method comprising:
forming a device layer on a substrate;
forming a through silicon via (TSV) opening in the substrate, the TSV opening including a dielectric collar and a bottom exposing the substrate;
forming an end cap in a bottom of the TSV opening, the end cap including a first metal; and
forming a TSV by forming a body including a second metal that is different than the first metal in the TSV opening.

9. The method of claim 8, further comprising:
bonding a handle wafer to a front side of the substrate over the device layer;
grinding a back side of the substrate until a surface of the end cap is exposed; and
forming a backside metallization to the end cap.

10. The method of claim 9, further comprising recessing the substrate beyond the surface of the end cap prior to forming the backside metallization.

11. The method of claim 8, wherein the TSV opening forming includes:
etching an opening into the substrate;
forming a dielectric layer over the opening; and
performing a spacer etch to expose the substrate in the bottom of the opening and form the dielectric collar.

12. The method of claim 11, wherein the end cap forming includes forming the second metal as a silicide on the bottom of the TSV opening, and
wherein the body forming includes depositing the first metal into the TSV opening over the end cap.

13. The method of claim 12, wherein the TSV opening forming further includes etching a recess into the substrate at the bottom of the opening.

14. The method of claim 13, wherein the end cap forming includes forming the first metal as a silicide on the bottom of the recess of the TSV opening, and
wherein the body forming includes depositing the second metal into the TSV opening over the end cap.

15. The method of claim 13, wherein the end cap forming includes selectively depositing the first metal in the bottom of the TSV opening, and
wherein the body forming includes depositing the second metal into the TSV opening over the end cap.

16. The method of claim 13, wherein the end cap forming includes blanket depositing the first metal into the TSV opening and etching the first metal to form the end cap, leaving the dielectric collar; and
wherein the body forming includes depositing the second metal into the TSV opening over the end cap.

17. The method of claim 13, wherein the end cap forming includes:
depositing the first metal on a sidewall of the opening and the bottom of the opening;
forming a resist plug over the first metal in the TSV opening;
etching to remove an upper portion of the first metal from the TSV opening, forming a first metal collar about the resist plug; and
etching to remove the resist plug,
wherein the body forming includes depositing the second metal into the TSV opening within the first metal collar and over the end cap.

18. The method of claim 8, wherein the first metal includes one of a silicide and a refractory metal, and the second metal includes copper.

19. A three dimensional integrated circuit comprising:
an integrated circuit chip including a through silicon via having:
a body including a first metal for coupling to an interconnect on a front side of the substrate;
a dielectric collar insulating the body from the substrate; and
an end cap coupled to the body on the back side of the substrate, the end cap including a second metal that is different than the first metal; and
a backside metallization coupled to the end cap on a back side of the substrate.

20. The three dimensional integrated circuit of claim 19, wherein the first metal includes copper and the second metal includes one of a silicide and a refractory metal.
